(19) United States
(12) Patent Application Publication
(10) Pub. No.: US 2015/0124200 A1
(43) Pub. Date: May 7, 2015

(54) COLOR FILTER SUBSTRATE, METHOD FOR FABRICATING THE SAME AND LIQUID CRYSTAL DISPLAY SCREEN

(71) Applicants: BOE TECHNOLOGY GROUP CO., LTD., Beijing (CN); BEIJING BOE DISPLAY TECHNOLOGY CO., LTD., Beijing (CN)

(72) Inventors: Jingjing Jiang, Beijing (CN); Min Li, Beijing (CN); Gyuhyun Lee, Beijing (CN); Hongjiang Wu, Beijing (CN)

(21) Appl. No.: 14/362,055

(22) PCT Filed: Jun. 17, 2013
(86) PCT No.: PCT/CN2013/077339

§ 371 Date: May 30, 2014

(30) Foreign Application Priority Data
Mar. 4, 2013 (CN) 201310067931.9

(51) Int. Cl. G02B 5/20; G03F 7/30; G02B 27/22; G02B 3/00; G02F 1/1335

(52) U.S. Cl. CPC G02B 5/201; G02B 3/0006; G02F 1/133514; G02F 1/133526; G02B 27/2207; G03F 7/30
USPC 349/95; 359/891; 430/321

(57) ABSTRACT

A color filter substrate and its fabrication method as well as a LCD screen are disclosed. The color filter substrate includes a base substrate, a plurality of color filter elements, and a microlens structure. The plurality of color filter elements are disposed on the base substrate, and the microlens structure is disposed on the plurality of color filter elements.

### FIELD OF THE ART

Embodiments of the invention relate to the field of liquid crystal display technologies, more particularly, to a color filter substrate, a method for fabricating the same and a liquid crystal display screen.

### BACKGROUND

With the development of display technologies, three-dimension (3D) display has become a key research topic in the display field following high definition displays. As naked-eye 3D technology can dismiss the constraint of glasses, it attracts much attention from customers and is getting more popular. A color filter substrate is an important component of a Thin Film Transistor Liquid Crystal Display (TFT-LCD) device.

FIG. 1 schematically illustrates a configuration of a known color filter substrate. The color filter substrate comprises a base substrate 11, a black matrix (BM) 12, a color filter element 13 and a protection layer 14 (also known as planarized layer). A post spacer 15 and other film layers (not shown) may also be disposed on the color filter substrate; the post spacer 15 is disposed on a side of the color filter substrate close to the liquid crystal layer. Herein, the color filter element 13 is generally a red color filter element, a green color filter element or a blue color filter element.

FIG. 2 schematically illustrates a configuration of a known naked-eye 3D LCD device, which mainly comprises a color filter substrate 10, an array substrate 20 (detail configuration of which not shown), a liquid crystal layer 30 and an optical device 40. The LCD device realizes naked-eye 3D display by using the optical device 40 to allow a user to view different pixels in the display screen from different visual angle.

The known device has the following disadvantages: 1. process procedures is complicated, making the production cycle long; 2. a series of optical device is introduced, which increases the production cost.

### SUMMARY

An embodiment of the invention provides a color filter substrate, which comprises a base substrate, a plurality of color filter elements, and a microlens structure, wherein the plurality of color filter elements are disposed on the base substrate, the microlens structure is disposed on the plurality of color filter elements.

As an example, the microlens structure is an array of multiple lenticular lenses.

As an example, each of the lenticular lenses covers two columns of pixel units of the color filter substrate; each pixel unit comprises a plurality of color filter elements.

As an example, a microlens material of the microlens structure is a transparent photoresist material.

As an example, the transparent photoresist material forms the microlens structure through a pattering process.

As an example, the color filter substrate further comprises a black matrix; the black matrix is disposed between the plurality of color filter elements.

An embodiment of the invention further provides a method for fabricating a color filter substrate; the method comprises the following steps:

forming a plurality of color filter elements on a base substrate;

coating a transparent photoresist on the substrate done with the previous step, exposing and developing the substrate having the photoresist coated thereon to form a patterned transparent layer on the substrate by using a mask;

performing a high-temperature process on the substrate done with the previous step, such that the transparent layer is in a molten state and forms a smooth convex surface under an effect of surface tension, and after getting cool, a microlens structure is formed on the substrate.

An embodiment of the invention further provides a method for fabricating a color filter substrate; the method comprises the following steps:

forming a plurality of color filter elements on a base substrate;

coating a transparent photoresist on the substrate done with the previous step, exposing and developing the substrate having the photoresist coated thereon to form a microlens structure on the substrate by using a gray-tone mask or a half-tone mask.

An embodiment of the invention further provides a LCD screen, which comprises an array substrate and a liquid crystal layer; the LCD screen further comprises the above color filter substrate.

### BRIEF DESCRIPTION OF THE DRAWINGS

In order to clearly illustrate the technical solution of the embodiments of the invention, the drawings of the embodiments will be briefly described in the following. It is obvious that the described drawings are only related to some embodiments of the invention and thus are not limitative of the invention.

FIG. 1 schematically illustrates a configuration of a known color filter substrate;

FIG. 2 schematically illustrates a configuration of a known naked-eye 3D LCD device;

FIG. 3 schematically illustrates a configuration of a color filter substrate in accordance with an embodiment of the invention;

FIG. 4 is a diagram illustrating the operating principle of a liquid crystal display screen in accordance with an embodiment of the invention;

FIG. 5 is a flow chart of fabricating a microlens in accordance with Embodiment 3 of the invention;

FIG. 6 is a flow chart of fabricating a microlens in accordance with Embodiment 4 of the invention;

FIG. 7 schematically illustrates a partial structural view of a half-tone mask in accordance with Embodiment 4 of the invention.

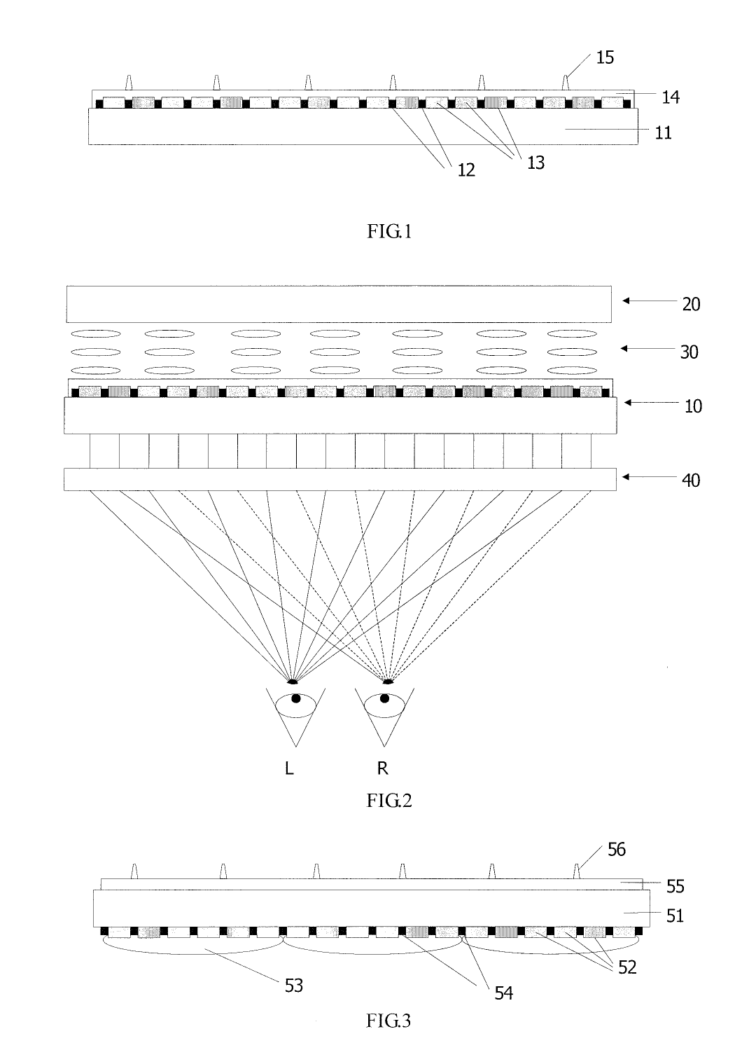

wherein, 11-base substrate; 12-BM; 13-color filter element; 14-protection layer; 15-post spacer; 10-color filter substrate; 20-array substrate; 30-liquid crystal layer; 40-optical device; 51-base substrate; 52-color filter element; 53-microlens structure; 54-BM; 55-protection layer; 56-post spacer; 57-color filter substrate; 60-mask; 70-exposure light beam; 61-half-tone mask; 61a-light-transmitting region; 61-1, 61-2, 61-n-sub light-transmitting regions.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

Unless otherwise defined, all the technical and scientific terms used herein have the same meanings as commonly understood by one of ordinary skill in the art to which the present invention belongs. The terms “first,” “second,” etc., which are used in the description and the claims of the present application for invention, are not intended to indicate any sequence, amount or importance, but distinguish various components. Also, the terms such as “a,” “an,” etc., are not intended to limit the amount, but indicate the existence of at least one. The terms “comprises,” “comprising,” “includes,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the position of the object which is described is changed, the relative position relationship may be changed accordingly.

### Embodiment 1

A color filter substrate according to the embodiment of the invention is illustrated in FIG. 3. The color filter substrate comprises a base substrate 51, a plurality of color filter elements 52, and a microlens structure 53; the plurality of color filter elements 52 are disposed on the base substrate 51, the microlens structure 53 is disposed on the plurality of color filter elements 52.

A color filter element 52 is generally a red color filter element, a green color filter element or a blue color filter element; it may also be color filter elements with other colors, such as a yellow color filter element. A pixel unit generally comprises a red color filter element, a green color filter element and a blue color filter element.

The microlens structure 53 is an array of multiple lenticular lenses. In the array, each of the lenticular lenses covers two columns of pixel units of the color filter substrate; each pixel unit comprises a plurality of color filter elements 52. As illustrated in FIG. 3, each lenticular lens covers six color filter elements 5. As an example, each pixel unit may comprise one or more groups of red, green and blue color filter elements.

A microlens material of the microlens structure is for example a transparent photoresist material.

The transparent photoresist material forms the microlens structure on a substrate through a pattering process.

As an example, the color filter substrate further comprises a black matrix (BM) 54; the BM is disposed between the color filter elements 52. The BM is configured for isolating the color filter elements 52 from each other, which helps to improve contrast ratio of colors and to reduce light leakage; the BM also provides alignment marks for fabricating the color filter elements (RGB).

As an example, the color filter substrate further comprise a protection layer 55 (also known as planarized layer), a post spacer 56 and a transparent conductive layer (not shown in FIG. 3), wherein the protection layer 55 and the post spacer 56 are disposed on a side of the base substrate 51 which is opposite to the microlens structure 53. The transparent conductive layer may be disposed on a side of the base substrate 51 which is opposite to the microlens structure 53 (referred to as a front side of the base substrate 51), or on the same side as the microlens structure 53 on the base substrate 51 (referred to as a back side of the base substrate 51), for example, the transparent conductive layer is disposed on a surface of the microlens structure 53, or between the base substrate 51 and the color filter elements 52, or between the color filter elements 52 and the microlens structure 53.

When the transparent conductive layer is disposed on the front side of the base substrate 51, the color filter substrate may be applied to a TN mode LCD screen, and the transparent conductive layer may function as a common electrode. When the transparent conductive layer is disposed on the back side of the base substrate 51, the color filter substrate may be applied to an ADS or IPS mode LCD screen, and the transparent conductive layer may function as an antistatic conductive layer.

With the color filter substrate provided by the above embodiments or examples, when two eyes view the display screen from different directions, different pixels are seen, thereby realizing the naked-eye 3D display. It has the following advantages in comparison with the known naked-eye 3D technology:

as the microlens structure 53 is fabricated on the color filter element 52, the image plane of the LCD screen is in the focal plane of the lenses, which allows a pixel of an image under the lenses to be divided into several pixels, hence, the microlens structure 53 can project each pixel along different directions; and

besides rendering the 3D display effect by the microlens structure 53 of the embodiments, the protection layer in fabrication of known color filter substrate is also omitted, thereby achieving the objective of simplifying the process procedures, shortening the production cycle and reducing the production cost. Such a color filter substrate is applicable to all type of LCDs.

### Embodiment 2

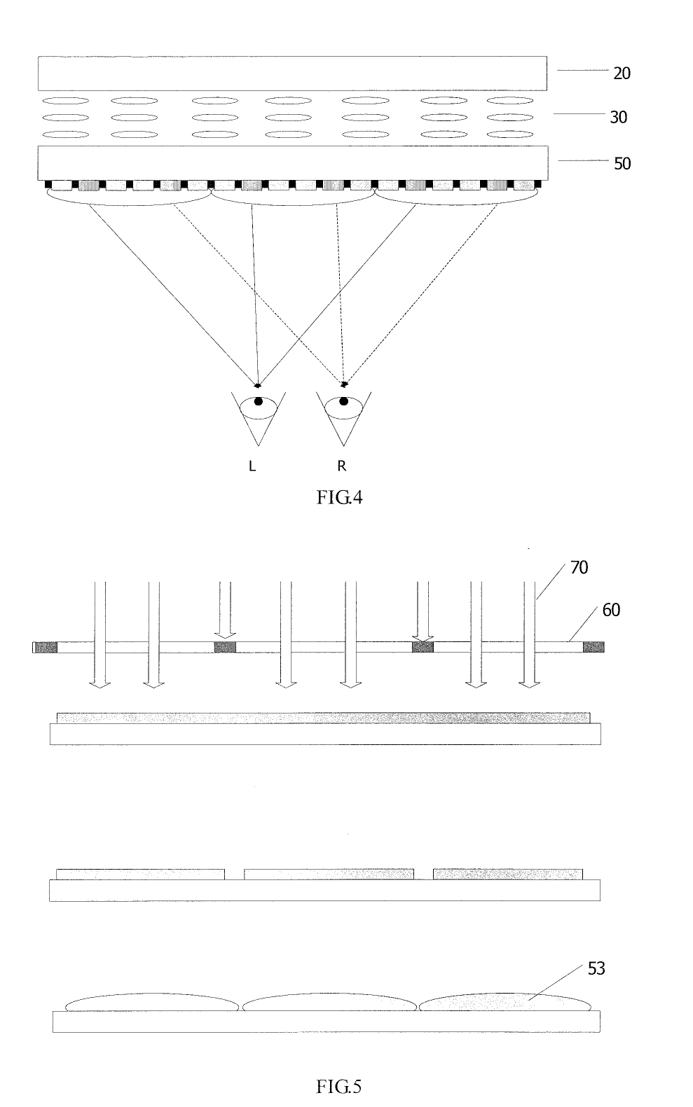

As illustrated in FIG. 4, the embodiment of the invention further provides a LCD screen, which comprises an array substrate 20 and a liquid crystal layer 30; the LCD screen further comprises the above color filter substrate 50 of Embodiment 1.

The color filter elements and the microlens structure in the color filter substrate 50 are disposed on a side of the LCD screen which is away from the liquid crystal layer 30.

The LCD screen provided by the above technical solution realizes the 3D display effect, and at the same time, it simplifies the process procedures, shortens the production cycle and reduces the production cost.

### Embodiment 3

As illustrated in FIG. 5, the embodiment of the invention further provides a method for fabricating the color filter substrate of Embodiment 1; the method comprises the following steps:

S1, forming a plurality of color filter elements on a base substrate;

As an example, a resin photoresist is coated on the base substrate, then the plurality of color filter elements are formed by exposing and developing the resin photoresist.

S2, coating a transparent photoresist on the base substrate done with the previous step, exposing and developing the base substrate having the photoresist coated thereon by way of a mask 60 to form a patterned transparent layer on the base substrate;

As an example, a layer of transparent photoresist is coated on the substrate having the color filter elements, and then a patterned transparent layer (the gray regions in the middle portion of FIG. 5) is formed after exposing and developing the transparent photoresist under an exposure light beam 70.

S3, finally, performing a high-temperature processing on the base substrate done with the previous step, such that the transparent layer is in a molten state and a smooth convex surface is formed under an effect of surface tension; after getting cooled, the microlens structure is formed. Herein, the high-temperature processing is a hot-melt moulding process. After subjected to the hot-melt process, the transparent layer is in a molten state, which then forms the smooth convex surface under the effect of surface tension.

In step S1, BM may be further formed between the plurality of color filter elements on the base substrate. The BM is configured for isolating the color filter elements from each other, which helps to improve contrast ratio of colors and to reduce light leakage; the BM also provides alignment marks for fabricating the color filter elements (RGB). As an example, the BM may be formed on the base substrate first, and then the color filter elements are formed. A method for forming the BM may be for example: coating a material for forming the BM on the base substrate, exposing and developing the material to form the BM by using a mask.

In step S1, a protection layer and a post spacer may be further formed on the front side of the base substrate.

In step S1, a transparent conductive layer may be further foamed on the front side of the base substrate. As described in Embodiment 1, the transparent conductive layer may also be formed on the back side of the base substrate. for example, formed on a surface of the microlens structure, or between the base substrate and the color filter elements, or between the color filter elements and the microlens structure.

When the transparent conductive layer is disposed on the front side of the base substrate 51, the color filter substrate may be applied to a TN mode LCD screen; when the transparent conductive layer is disposed on the back side of the base substrate 51, the color filter substrate may be applied to an ADS or IPS mode LCD screen.

In the method for fabricating the color filter substrate provided by the above embodiment, the microlens structure is directly formed on the base substrate through the patterning process, thereby improving the alignment precision of the lenses. Besides rendering the 3D display effect by the microlens structure, the protection layer in fabrication of the known color filter substrate is also omitted, thereby achieving the objective of simplifying the process procedures, shortening the production cycle and reducing the production cost. The color filter substrate fabricated by the method is applicable to all type of LCDs.

### Embodiment 4

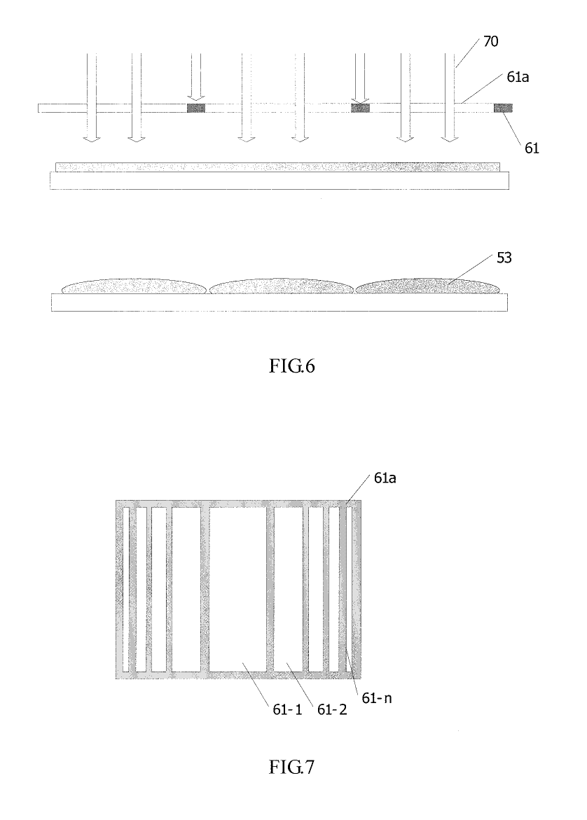

As illustrated in FIG. 6, the embodiment of the invention further provides another method for fabricating the color filter substrate of Embodiment 1; the method comprises the following steps:

S1, forming a plurality of color filter elements on a base substrate;

As an example, a resin photoresist is coated on the base substrate, then the plurality of color filter elements are formed by exposing and developing the resin photoresist.

S2, coating a transparent photoresist on the base substrate done with the previous step, exposing and developing the base substrate having the photoresist coated thereon to form a microlens structure on base the substrate by using a gray-tone mask or a half-tone mask.

As an example, a layer of transparent photoresist is coated on the base substrate having the color filter elements, and then a gray-tone mask or a half-tone mask 61 is used to expose and develop the base substrate having the photoresist coated thereon under the exposure light beam 70. Herein, the mask 61 comprises a plurality of light-transmitting regions 61a, light transmissivity of each light-transmitting region 61a presents gradient change (for example, the light transmissivity decreases from a center of the region 61 to both sides). After developing, a thickness of the photoresist layer decreases gradually from the center to the edges, thus, the microlens structure 53 having a smooth convex surface is formed. The microlens structure may be further undergone a high-temperature drying process, so as to improve the surface flatness of the microlens structure.

As illustrated in FIG. 7, each light-transmitting region 61a comprises a plurality of sub-light-transmitting region 61-1, 61-2, . . . , 61n (that is, light-transmitting slits).The widths of the light-transmitting slits decrease from the center of the region 61 to both sides, thereby making the transmissivity of the light-transmitting region 61a decrease from the center to both sides.

In step S1, BM may be further formed between the plurality of color filter elements on the base substrate, so as to improve the light shielding effect.

In step S1, a protection layer and a post spacer may be further formed on a side of the base substrate which is opposite to the microlens structure 53.

In step S1, a transparent conductive layer may be further formed on a side of the base substrate which is opposite to the microlens structure 53.

Furthermore, the above transparent conductive layer may also be formed on the same side as the microlens structure 53 on the base substrate 51, for example, between the base substrate and the color filter elements, or between the color filter elements and the microlens structure.

When the transparent conductive layer is disposed on the front side of the base substrate 51, the color filter substrate may be applied to a TN mode LCD screen; when the transparent conductive layer is disposed on the back side of the base substrate 51, the color filter substrate may be applied to an ADS or IPS mode LCD screen.

In the method for fabricating the color filter substrate provided by the above embodiment, the microlens structure is directly formed on the glass substrate through the patterning process, thereby improving the alignment precision of the lenses. Besides rendering the 3D display effect by the microlens structure, the protection layer in fabrication of the known color filter substrate is also omitted, thereby achieving the objective of simplifying the process procedures, shortening the production cycle and reducing the production cost. The color filter substrate fabricated by the method is applicable to all type of LCDs.

What are described above is related to the illustrative embodiments of the disclosure only and not limitative to the scope of the disclosure; the scopes of the disclosure are defined by the accompanying claims.

1. A color filter substrate, comprising a base substrate, a plurality of color filter elements, and a microlens structure, wherein the plurality of color filter elements are disposed on the base substrate, the microlens structure is disposed on the plurality of color filter elements.

2. The color filter substrate of claim 1, wherein the microlens structure is an array of multiple lenticular lenses.

3. The color filter substrate of claim 2, wherein each of the lenticular lenses covers two columns of pixel units of the color filter substrate, each pixel unit comprises a plurality of color filter elements.

4. The color filter substrate of claim 1, wherein a microlens material of the microlens structure is a transparent photoresist material.

5. The color filter substrate of claim 4, wherein the transparent photoresist material forms the microlens structure through a pattering process.

6. The color filter substrate of claim 1, wherein the color filter substrate further comprises black matrix, the black matrix is disposed between the plurality of color filter elements.

7. A method for fabricating a color filter substrate, comprising the following step:
forming a plurality of color filter elements on a base substrate;
coating a transparent photoresist on the substrate done with the previous step, exposing and developing the substrate having the transparent photoresist coated thereon to form a patterned transparent layer on the base substrate by using a mask;
performing a high-temperature process on the substrate done with the previous step, such that the transparent layer is in a molten state and forms a smooth convex surface under an effect of surface tension, and after getting cool, a microlens structure is formed on the substrate.

8. A method for fabricating a color filter substrate, comprising the following steps:
forming a plurality of color filter elements on a base substrate;
coating a transparent photoresist on the substrate done with the previous step, exposing and developing the substrate having the transparent photoresist coated thereon by using a gray-tone or half-tone mask, to form a microlens structure on the substrate.

9. The fabrication method of claim 8, wherein the gray-tone or half-tone mask comprises a plurality of light-transmitting regions, and light transmissivity of each light-transmitting region presents gradient change.

10. The fabrication method of claim 9, wherein the light transmissivity presenting gradient change decreases from a center of the light-transmitting region to both sides of the light-transmitting region.

11. A LCD screen, comprising an array substrate and a liquid crystal layer; the LCD screen further comprising the color filter substrate of claim 1.

12. The LCD screen of claim 11, wherein both the color filter elements and the microlens structure of the color filter substrate are disposed on a side of the LCD screen which is away from the liquid crystal layer.
